(19) United States
(12) Patent Application Publication
(10) Pub. No.: US 2026/0333616 A1
(43) Pub. Date: Oct. 22, 2026

(54) COOLING MODULE AND ELECTRONIC APPARATUS

(71) Applicant: Lenovo (Singapore) Pte. Ltd., Singapore (SG)

(72) Inventors: Takahisa Moriwaki, Kanagawa (JP); Masahiro Kitamura, Kanagawa (JP)

(73) Assignee: Lenovo (Singapore) Pte. Ltd., Singapore (SG)

(21) Appl. No.: 19/302,789

(22) Filed: Aug. 18, 2025

(30) Foreign Application Priority Data
Aug. 20, 2024 (JP) 2024-138985

(51) Int. Cl. H05K 7/20; G06F 1/20

(52) U.S. Cl. CPC H05K 7/20154; G06F 1/20; H05K 7/20336; H05K 7/2039

(57) ABSTRACT

A cooling module is mounted in an electronic apparatus and includes a fan having an outlet port, and a heat sink having a plurality of fins arranged with a gap between the plurality of fins between a first plate-like portion and a second plate-like portion that extend along a width direction of the outlet port, the heat sink being disposed to face the outlet port, in which the first plate-like portion includes an opening portion through which a part of air ejected from the outlet port is capable of being discharged, and an auxiliary opening portion that is provided between at least one end located on a downstream side in an air flow direction in the fan in a longitudinal direction of the first plate-like portion and the opening portion, and through which a part of air ejected from the outlet port is capable of being discharged.

### CROSS-REFERENCE TO RELATED APPLICATIONS

This application claims priority to Japanese Patent Application No. 2024-138985 filed on Aug. 20, 2024, the contents of which are hereby incorporated herein by reference in their entirety.

### TECHNICAL FIELD

Embodiments of the present invention relate to a cooling module and an electronic apparatus including the cooling module.

### BACKGROUND

An electronic apparatus, such as a laptop PC, is equipped with a cooling module for cooling a heating element, such as a CPU (for example, see Japanese Unexamined Patent Application Publication No. 2022-117678). Such a cooling module has a configuration including a heat pipe that absorbs and transports the heat generated by the CPU or the like, and a heat sink and a fan that discharge the heat transported by the heat pipe to the exterior of a chassis.

There is a high demand for reduction in size and thickness of the electronic apparatus as described above. Therefore, a heat sink mounted in the electronic apparatus is also reduced in size and thickness. In addition, it is desirable to minimize a fin pitch in the heat sink in consideration of heat exchange efficiency. Therefore, in a case in which the electronic apparatus is used for a long period of time or is used in a harsh environment in which there is a lot of debris, dirt, or the like (dust), there is a concern that dust gradually clogs the heat sink and the air-flow resistance increases. In this case, there is a concern that the cooling module has a deterioration in heat exchange performance in the heat sink, leading to a gradual deterioration in the cooling performance thereof.

In the heat sink of Japanese Unexamined Patent Application Publication No. 2022-117678, an opening portion having a cutout shape is formed at the center of one surface side in an upright direction of the fins, so that the air-flow resistance can be reduced and an amount of air from the fan can be increased. Further, the opening portion also contributes to the discharge of the dust. The opening portion is not formed at both ends of the heat sink in the width direction. This is to prevent air blow to both end sides of the heat sink. Therefore, the dust is likely to be clogged at both ends of the heat sink in which the opening portion is not provided, as compared to the center, and there is a concern that cooling performance may deteriorate.

### SUMMARY

Embodiments of the present invention provide a cooling module capable of maintaining cooling performance for a longer period of time and an electronic apparatus including the cooling module.

A first aspect of the present invention relates to a cooling module that is mounted in an electronic apparatus, the cooling module including: a fan having an outlet port; and a heat sink having a plurality of fins arranged with a gap between the plurality of fins between a first plate-like portion and a second plate-like portion that extend along a width direction of the outlet port, the heat sink being disposed to face the outlet port, in which the first plate-like portion includes an opening portion through which a part of air ejected from the outlet port is capable of being discharged, and an auxiliary opening portion that is provided between at least one end located on a downstream side in an air flow direction in the fan in a longitudinal direction of the first plate-like portion and the opening portion, and through which a part of air ejected from the outlet port is capable of being discharged, and an opening area of the auxiliary opening portion is smaller than an opening area of the opening portion.

A second aspect of the present invention relates to an electronic apparatus including: a chassis; a heating element provided in the chassis; and a cooling module provided in the chassis and configured to cool the heating element, in which the cooling module includes a fan having an outlet port, and a heat sink having a plurality of fins arranged with a gap between the plurality of fins between a first plate-like portion and a second plate-like portion that extend along a width direction of the outlet port, the heat sink being disposed to face the outlet port, the first plate-like portion includes an opening portion through which a part of air ejected from the outlet port is capable of being discharged, and an auxiliary opening portion that is provided between at least one end located on a downstream side in an air flow direction in the fan in a longitudinal direction of the first plate-like portion and the opening portion, and through which a part of air ejected from the outlet port is capable of being discharged, and an opening area of the auxiliary opening portion is smaller than an opening area of the opening portion.

Embodiments of the present invention can maintain cooling performance for a longer period of time.

### BRIEF DESCRIPTION OF THE DRAWINGS

FIG. 1 is a schematic plan view of an electronic apparatus according to one or more embodiments as viewed from above.

FIG. 2 is a plan view schematically illustrating an internal structure of a chassis, in accordance with one or more embodiments.

FIG. 3 is a perspective view of a heat sink and a fan, in accordance with one or more embodiments.

FIG. 4A is a perspective view of the heat sink, in accordance with one or more embodiments.

FIG. 4B is a perspective view of the heat sink illustrated in FIG. 4A as viewed from an opposite direction, in accordance with one or more embodiments.

FIG. 5 is a plan view of the heat sink, in accordance with one or more embodiments.

FIG. 6 is a schematic cross-sectional view taken along line VI-VI in FIG. 5, in accordance with one or more embodiments.

FIG. 7A is a front view of an auxiliary opening portion of the heat sink and a peripheral portion thereof in a disassembled manner, in accordance with one or more embodiments.

FIG. 7B is a front view illustrating a state in which fins illustrated in FIG. 7A are joined to each other, in accordance with one or more embodiments.

FIG. 8 is a plan view of the heat sink having a plate-like portion according to a modification example, in accordance with one or more embodiments.

### DETAILED DESCRIPTION

Hereinafter, embodiments of a cooling module and an electronic apparatus according to the present invention will be described in detail with reference to the accompanying drawings.

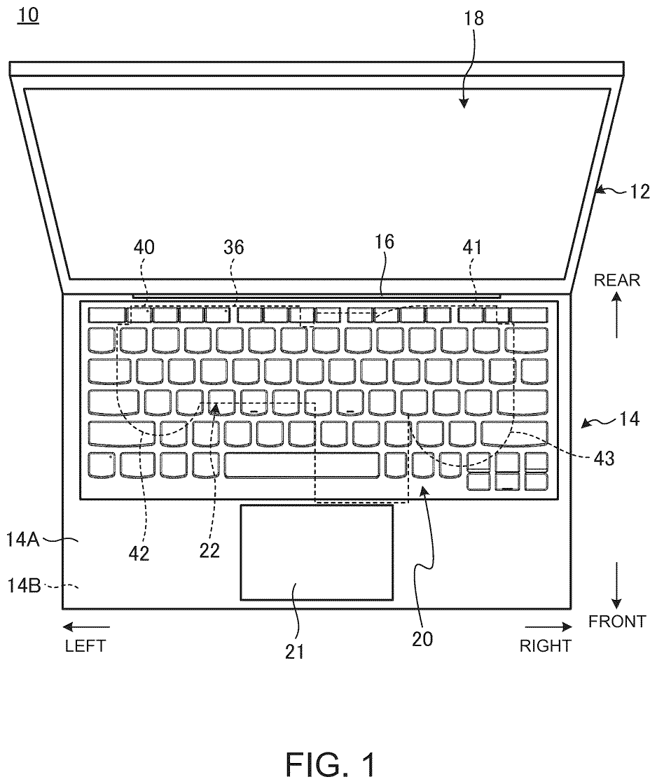

FIG. 1 is a schematic plan view of an electronic apparatus 10 according to one or more embodiments as viewed from above. As illustrated in FIG. 1, the electronic apparatus 10 is a clamshell-type laptop PC in which a display chassis 12 and a chassis 14 are coupled to each other by a hinge 16 so as to be relatively rotatable. The electronic apparatus according to the present invention may be, for example, a desktop PC, a tablet PC, a smartphone, a game machine, or the like, in addition to the laptop PC.

The display chassis 12 is a thin, flat, and box-shaped body. A display 18 is mounted on the display chassis 12. The display 18 includes, for example, an organic EL (organic light emitting diode, OLED) or a liquid crystal.

Hereinafter, with respect to the chassis 14 and each element mounted on the chassis 14, the description will be made by setting a space between the chassis 12 and 14 to be in an open state as illustrated in FIG. 1, using a posture of visually recognizing the display 18 as a reference, defining a front side to as front, defining a rear side to as rear, defining a width direction to as left and right, and defining a height direction (thickness direction of the chassis 14) to as top and bottom.

The chassis 14 is a thin, flat, and box-shaped body. The chassis 14 includes a cover member 14A that forms an upper surface and four peripheral side surfaces, and a cover member 14B that forms a lower surface. The cover member 14A on the top side has a substantially bathtub shape with a lower surface open. The cover member 14B on the bottom side has a substantially flat plate shape and serves as a lid that closes the lower surface opening of the cover member 14A. The cover members 14A and 14B overlap each other in the thickness direction and are detachably coupled to each other. A keyboard 20 and a touch pad 21 are provided on the upper surface of the chassis 14. A rear end portion of the chassis 14 is coupled to the display chassis 12 by using the hinge 16.

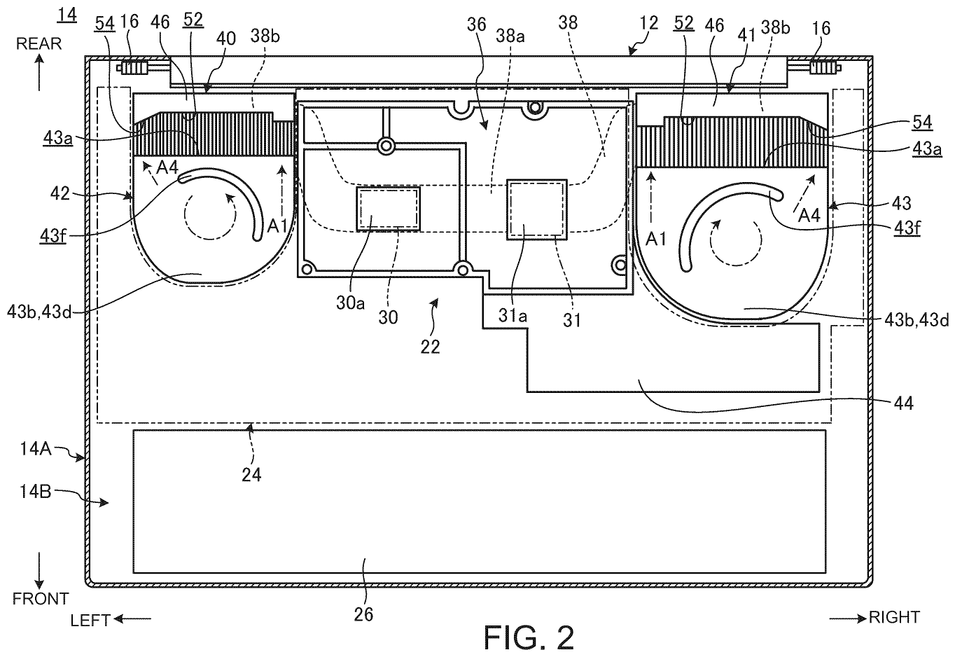

FIG. 2 is a plan view schematically illustrating an internal structure of the chassis 14, and is a schematic plan cross-sectional view of the chassis 14 cut slightly below the keyboard 20.

As illustrated in FIG. 2, a cooling module 22, a motherboard 24, and a battery device 26 are provided inside the chassis 14. Various electronic components, mechanical components, and the like are further provided inside the chassis 14.

The motherboard 24 is a main board of the electronic apparatus 10. The motherboard 24 is disposed near the rear of the chassis 14 and extends along the left-right direction. The motherboard 24 is a printed board on which various electronic components, such as a power component, a communication module, a memory, and a connection terminal are mounted in addition to a CPU 30 and a GPU 31. The motherboard 24 is disposed below the keyboard 20 and is screwed to a rear surface of the keyboard 20 or an inner surface of the cover member 14A. The motherboard 24 has an upper surface that serves as an attachment surface with respect to the cover member 14A, and a lower surface that serves as a mounting surface with respect to the CPU 30 and the like.

The CPU 30 is disposed on the left side of the center on the left and right of the mounting surface of the motherboard 24. The CPU 30 performs computing related to main control or processing of the electronic apparatus 10. The GPU 31 is arranged on the right side of the CPU 30 on the mounting surface of the motherboard 24. The GPU 31 performs computing necessary for image depiction, such as 3D graphics.

The battery device 26 is a rechargeable battery that serves as a power source of the electronic apparatus 10. The battery device 26 is disposed in front of the motherboard 24 and extends to a left-right direction along a front end portion of the chassis 14.

Hereinafter, a configuration of the cooling module 22 will be described.

The CPU 30 and the GPU 31 are heating elements having the largest calorific value among the electronic components mounted in the chassis 14. Therefore, the cooling module 22 absorbs and diffuses the heat generated by the CPU 30 and the GPU 31, and further discharges the heat to the outside of the chassis 14. The cooling module 22 is laminated to cover a part of the mounting surface of the motherboard 24, for example.

As illustrated in FIG. 2, the cooling module 22 can include a vapor chamber 36, a heat pipe 38, a pair of left and right heat sinks 40 and 41, a pair of left and right fans 42 and 43, and a heat conductive plate 44.

The vapor chamber 36 is a plate-shaped heat transport device. The vapor chamber 36 forms a closed space between two thin metal plates, and a working fluid is enclosed in the closed space. The metal plate is formed of a metal having high heat conductivity, such as aluminum, copper, or stainless steel. The closed space serves as a flow path through which the enclosed working fluid flows while causing a phase change. Examples of the working fluid include water, chlorofluorocarbon substitutes, acetone, butane, and the like. A wick that delivers the condensed working fluid by a capillary phenomenon is disposed in the closed space. The wick is formed of, for example, a porous body, such as a mesh obtained by knitting a fine metal wire into a cotton shape, or a fine flow path.

The vapor chamber 36 can absorb and diffuse the heat of the CPU 30 and the GPU 31, and transfer the heat to the heat pipe 38 connected to a lower surface. Reference numerals 30a and 31a in FIG. 2 are heat receiving plates interposed between an upper surface of the vapor chamber 36 and top surfaces of the CPU 30 and the GPU 31, respectively, and are copper plates, for example.

The heat pipe 38 is a pipe-shaped heat transport device. The heat pipe 38 is configured such that a metal pipe is thinly and flatly crushed and is formed to have an elliptical-shaped cross section, and the working fluid is enclosed in the closed space formed in the metal pipe. The materials and configurations of the metal pipe, the closed space, the working fluid, and the wick constituting the heat pipe 38 may be the same as or similar to the materials and configurations of the metal plate, the closed space, the working fluid, and the wick constituting the vapor chamber 36.

In the heat pipe 38 according to one or more embodiments, the vicinity of the center is curved to the front side, is formed in a substantially U shape in plan view, and extends in the left-right direction. A central portion 38a of the heat pipe 38 is connected to the lower surface of the vapor chamber 36 at a position overlapping the CPU 30 and the GPU 31 in the top-bottom direction. The heat pipe 38 has one end portion 38b connected to a lower surface of the heat sink 40, and has the other end portion 38b connected to a lower surface of the heat sink 41. Two or more heat pipes 38 may be used in parallel. In a case in which only one set of the heat sink and the fan is mounted in the cooling module 22, the heat pipe 38 may have one end portion connected to the CPU 30 or the GPU 31 and have the other end portion connected to the heat sink.

The heat conductive plate 44 is coupled to a front edge portion of the vapor chamber 36 and protrudes forward. The heat conductive plate 44 is a thin plate formed of a metal, such as aluminum or copper, or a material having high heat conductivity, such as graphite.

Hereinafter, the configurations of the heat sinks 40 and 41 and the fans 42 and 43 will be described.

As illustrated in FIG. 2, the left and right heat sinks 40 and 41 are slightly different in size, heat exchange area, and the like, but can have a substantially symmetrical structure. Similarly, the left and right fans 42 and 43 can also be made to have a substantially symmetrical structure. Therefore, hereinafter, the heat sink 41 and the fan 43 on the right side will be mainly described, the heat sink 40 and the fan 42 on the left side will be denoted by the same reference numerals as the right side, and the detailed description thereof will be omitted. In addition, the fans 42 and 43 and the heat sinks 40 and 41 may be configured by only one of a left and right pair, not by a left and right pair.

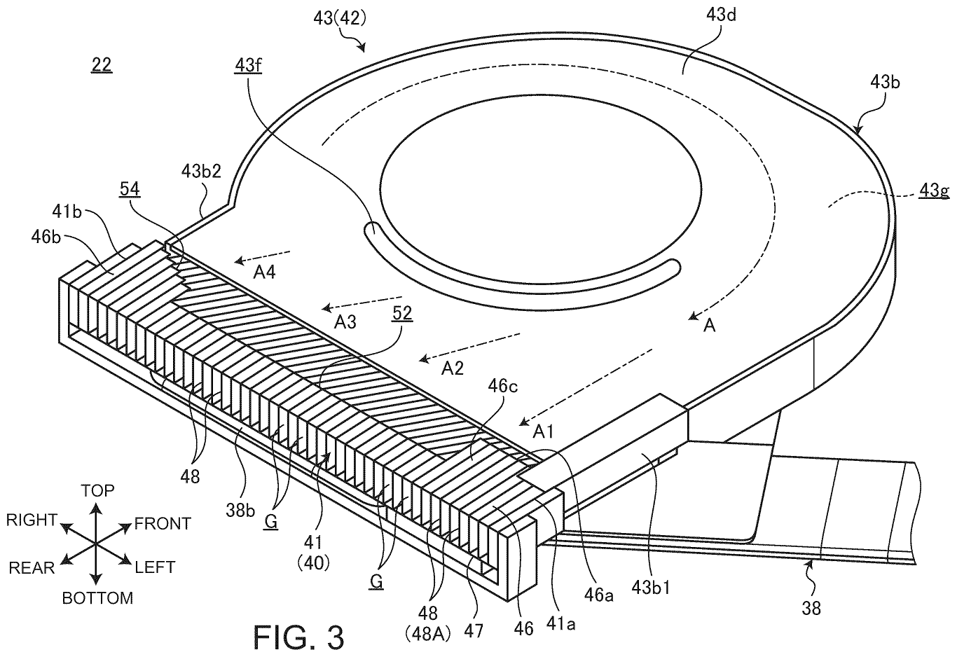

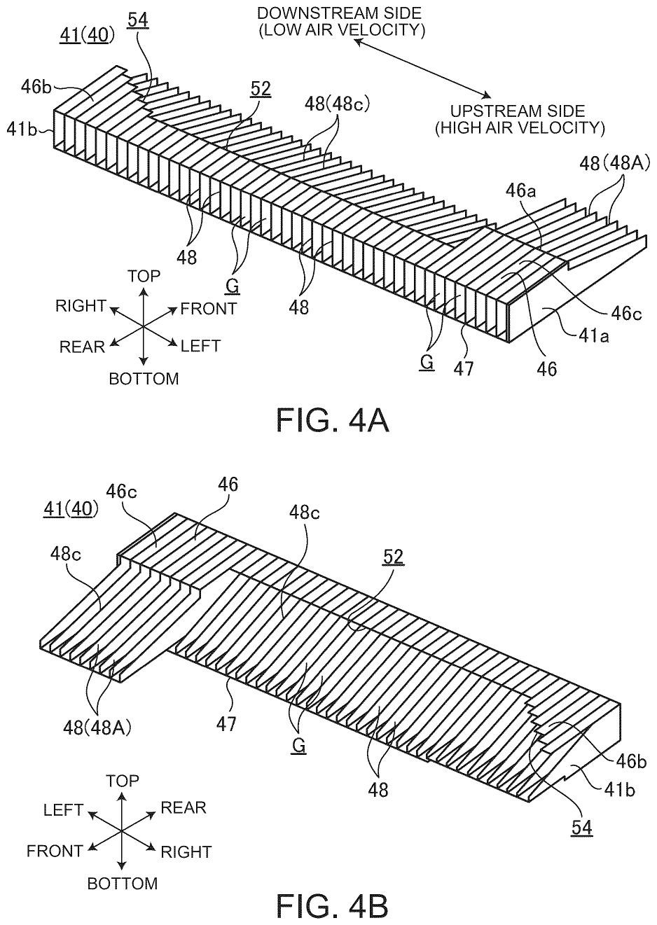

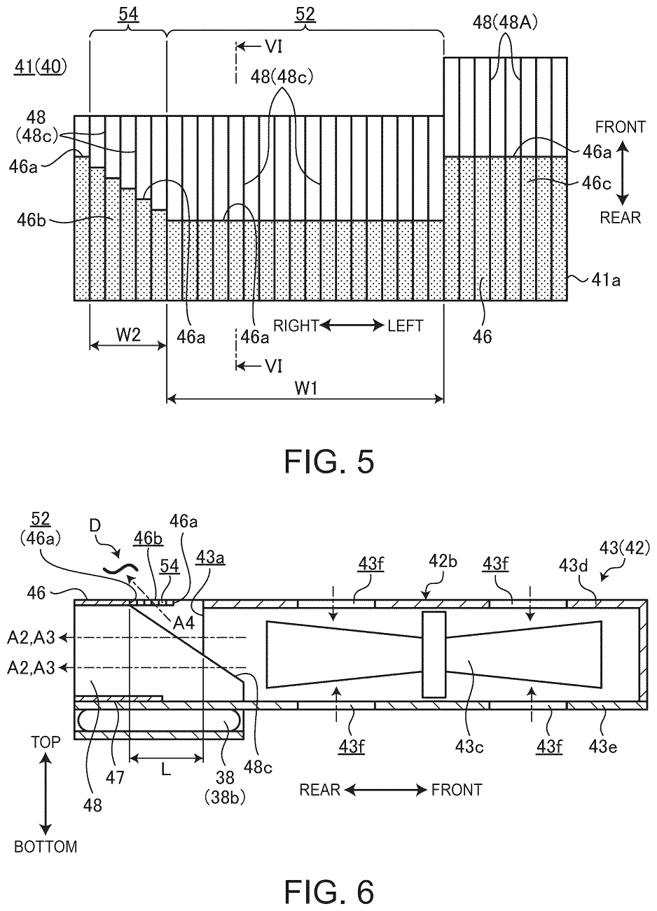

FIG. 3 is a perspective view of the heat sink 41 and the fan 43. FIG. 4A is a perspective view of the heat sink 41. FIG. 4B is a perspective view of the heat sink 41 illustrated in FIG. 4A as viewed from an opposite direction. FIG. 5 is a plan view of the heat sink 41. FIG. 6 is a schematic cross-sectional view taken along line VI-VI in FIG. 5.

As illustrated in FIGS. 2, 3, and 6, the fan 43 has a fan chassis 43b in which an outlet port 43a is formed to be open on one side surface. The fan 43 is disposed immediately before the heat sink 41, and the outlet port 43a that is open rearward is disposed to face a front surface of the heat sink 41. The fan 43 is a centrifugal fan that rotates an impeller 43c housed in the fan chassis 43b by a motor. The fan chassis 43b can be configured with, for example, a cover plate 43d forming an upper surface and a side surface, and a cover plate 43e forming a lower surface. Each of the cover plates 43d and 43e has an intake port 43f open therein. The intake port 43f may be provided on only one of the cover plates 43d and 43e.

An air path 43g is formed inside the fan chassis 43b. The air path 43g is an air flow path that extends from the intake port 43f to the outlet port 43a through the periphery of the impeller 43c. A dash-dot arrow illustrated in FIG. 3 schematically indicates an airflow, and the same applies to FIG. 6 and the like.

Air A in FIG. 3 has an airflow that is introduced from the intake port 43f, flows through the air path 43g formed in the periphery of the impeller 43c, is gradually compressed, and reaches the outlet port 43a while increasing the air velocity. The outlet port 43a is wider than the air path 43g. Therefore, the air velocity of the air A ejected from the outlet port 43a gradually decreases from a wall portion 43b1 located on an upstream side of the outlet port 43a in a width direction (left-right direction) to a wall portion 43b2 located on a downstream side thereof. As schematically illustrated in FIG. 3, in the air ejected from the outlet port 43a, air A1 on the upstream side has the highest air velocity, air A2 and air A3 have the next highest air velocity in this order, and air A4 on the downstream side has the lowest air velocity. The air velocity of the air actually ejected from the outlet port 43a of the fan 43 cannot be digitally classified as in the air A1 to A4, but is changed in an analog manner, and the air velocity may be reversed between the upstream side and the downstream side in a case of a small range. In consideration of such a point, in one or more embodiments, the air velocity of the air ejected from the outlet port 43a is illustrated in four stages of the air A1 to A4.

As illustrated in FIGS. 2 to 6, the heat sink 41 (40) includes plate-like portions 46 and 47, a plurality of fins 48 erected in the top-bottom direction and arranged in the left-right direction between the plate-like portions 46 and 47, an opening portion 52, and an auxiliary opening portion 54. The plate-like portions 46 and 47 and the fins 48 can be formed of a metal having high heat conductivity, such as copper, aluminum, or stainless steel.

The plate-like portions 46 and 47 are portions that form the upper and lower surfaces of the heat sink 41, and are parallel to each other with an interval of an upright height of the fins 48 therebetween. The plate-like portions 46 and 47 are disposed in parallel with the upper surface and the lower surface of the fan chassis 43b, respectively. The plate-like portion (first plate-like portion) 46 on the top side is disposed on substantially the same plane as the upper surface of the fan chassis 43b and closes an upper surface opening of a gap G between the fins 48. The plate-like portion (second plate-like portion) 47 on the bottom side is disposed on substantially the same plane as the lower surface of the fan chassis 43b and closes a lower surface opening of the gap G between the fins 48. The end portion 38b of the heat pipe 38 is joined to an outer surface (lower surface) of the plate-like portion 47 by welding or the like.

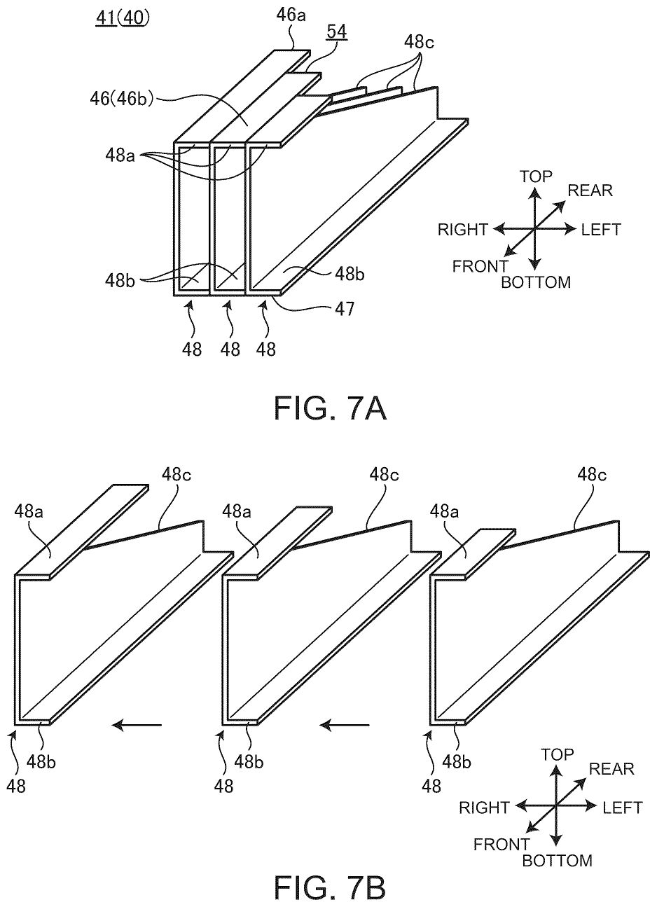

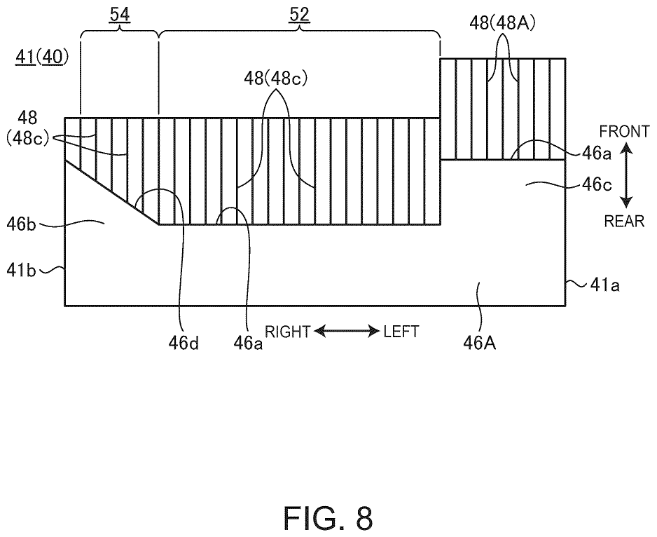

Although details will be described later, as illustrated in FIGS. 7A and 7B, the heat sink 41 according to one or more embodiments forms the plate-like portions 46 and 47 by arranging plate pieces 48a and 48b of each fin 48 in the left-right direction. Each of the plate-like portions 46 and 47 may be formed of one metal plate (see FIG. 8).

The fins 48 are formed of thin plates erected in the top-bottom direction between the plate-like portions 46 and 47 and extending in the front-rear direction. The fins 48 are arranged with the gap G therebetween along a width direction (left-right direction) of the heat sink 41 along the width direction of the outlet port 43a. Accordingly, in the heat sink 41, the gap G between the adjacent fins 48 serves as an air flow path through which air from the outlet port 43a passes. A fin pitch (width of the gap G) between the respective fins 48 can be, for example, 1 mm. As illustrated in FIGS. 4A, 4B, and 6, each fin 48 can be provided with an inclined shape portion 48c at a portion that protrudes from an edge portion 46a of the plate-like portion 46, an opening portion 52, and the auxiliary opening portion 54 toward the outlet port 43a side. The inclined shape portion 48c is gradually inclined downward from an outlet side (rear side) of the heat sink 41 toward the outlet port 43a side (front side), and is inserted into the fan chassis 43b.

As illustrated in FIGS. 2 to 6, the opening portion 52 and the auxiliary opening portion 54 can be formed as a recessed opening formed by cutting out a part of the edge portion 46a of the plate-like portion 46 on the top side, which faces the outlet port 43a, in a direction away from the outlet port 43a. In FIG. 5, the shape of the plate-like portion 46 is clearly illustrated by applying a dot pattern.

First, the opening portion 52 can be formed in a range including the center of the heat sink 41 in the width direction. The opening portion 52 forms a bypass path through which a part of the air ejected from the outlet port 43a can be bypassed and discharged in front. The opening portion 52 can be provided at a central portion excluding a predetermined range from an end 41a on an upstream side and a predetermined range from an end 41b on a downstream side, with a width direction of the heat sink 41 as a reference. That is, the opening portion 52 according to one or more embodiments is not provided on the sides of both ends 41a and 41b of the heat sink 41.

As illustrated in FIGS. 4A and 4B, each fin 48 (hereinafter, also referred to as a “fin 48A”) located at a position close to the end 41a located on the upstream side in which the opening portion 52 is not provided can have a longer length in the air flow direction (the front-rear direction) than the fin 48 at other portions.

Next, the auxiliary opening portion 54 can be provided between the opening portion 52 and the end (one end) 41b located on the downstream side in the air flow direction in the fan 43. An opening area of the auxiliary opening portion 54 is smaller than an opening area of the opening portion 52.

First, the fact that the opening area of the auxiliary opening portion 54 is smaller than the opening area of the opening portion 52 means that the auxiliary opening portion 54 is smaller than the opening portion 52 in terms of an area ratio of the opening portion in simple plan view. Here, the opening portions of the opening portion 52 and the auxiliary opening portion 54 in plan view are cutout areas from the edge portion 46a located at a position closest to the outlet port 43a to the opening portion 52 and the edge portion 46a that is a front edge of the auxiliary opening portion 54. As illustrated in FIG. 5, a dimension of the opening portion 52 in the width direction (left-right direction) of the heat sink 41 is referred to as a width W1, and a dimension of the auxiliary opening portion 54 in the width direction is referred to as a width W2. In the configuration example illustrated in FIG. 5, the lengths, in the front-rear direction, of the fins 48 located at positions overlapping the opening portion 52 and the auxiliary opening portion 54 in the top-bottom direction are the same. In this case, the width W2 can be set to, for example, 10% to 30% of the width W1. As described above, in a case in which the fin pitch is, for example, 1 mm, the width W1 of the opening portion 52 can be set to, for example, about 30 mm to 60 mm, and the width W2 of the auxiliary opening portion 54 can be set to, for example, about 3 mm to 20 mm.

Second, it can be said that the fact that the opening area of the auxiliary opening portion 54 is smaller than the opening area of the opening portion 52 means that the opening area per unit width along the width direction of the heat sink 41 is small. In other words, it can be said that the auxiliary opening portion 54 has a shorter distance L (see FIG. 6) in the front-rear direction from the edge portion 46a to the outlet port 43a than the opening portion 52. In one or more embodiments, the auxiliary opening portion 54 is configured such that the width W2 is smaller than the width W1 of the opening portion 52 and the distance L is also smaller than in the opening portion 52. Accordingly, excessive air blow from the auxiliary opening portion 54 is prevented as will be described later, and dust D can be discharged more smoothly.

The auxiliary opening portion 54 according to one or more embodiments can be formed such that the opening area gradually decreases from the opening portion 52 toward the end 41b. That is, the distance L from the edge portion 46a of the auxiliary opening portion 54 to the outlet port 43a gradually decreases from a boundary with the opening portion 52 toward the end 41b. As a result, the edge portion 46a forming the front edge of the auxiliary opening portion 54 can be formed in a stepped or linear shape inclined with respect to the width direction. Therefore, a portion 46b of the plate-like portion 46 adjacent to the auxiliary opening portion 54 has a substantially trapezoidal shape in plan view.

In the plate-like portion 46, a portion 46c located close to the end 41a on the side opposite to the opening portion 52 forms a substantially rectangular shape in plan view. The edge portion 46a of the portion 46b adjacent to the end 41b and the edge portion 46a of the portion 46c have positions in the air flow direction (front-rear direction) in the heat sink 41 that coincide or substantially coincide with each other, and are close to the outlet port 43a (see FIGS. 5 and 6).

As described above, the cooling module 22 according to one or more embodiments includes the plurality of fins 48 arranged with the gap G provided therebetween, between the plate-like portions 46 and 47 extending along the width direction of the outlet port 43a of the fan 43, and the heat sink 41 that is disposed to face the outlet port 43a. The plate-like portion 46 has the opening portion 52 through which a part of the air ejected from the outlet port 43a can be discharged. Further, the plate-like portion 46 has the auxiliary opening portion 54 that is provided between at least the end 41b located on the downstream side in the air flow direction in the fan 43, and the opening portion 52 in the longitudinal direction (left-right direction) thereof. The auxiliary opening portion 54 can also discharge a part of the air ejected from the outlet port 43a. In the heat sink 41, the opening area of the auxiliary opening portion 54 is smaller than the opening area of the opening portion 52.

The cooling module 22 can bypass a part of the air from the outlet port 43a through the opening portion 52 and the auxiliary opening portion 54. Accordingly, the heat sink 41 can reduce the air-flow resistance of the air passing through a narrow gap G, and can increase the amount of air from the fan 43 to improve the heat exchange performance.

The opening portion 52 and the auxiliary opening portion 54 also function as a discharge port that discharges the dust D sucked into the fan 43 together with air and ejected from the outlet port 43a toward the heat sink 41 (see FIG. 6). Examples of the dust D include debris, dirt, fibers, and hair. As described above, in the heat sink 41, the fin pitch between the fins 48 is small, for example, about 1 mm, and there is a concern that dust D of, for example, about several millimeters in size clogs the fin. In a case in which the heat sink 41 is clogged with the dust D, there is a concern that an amount of air passing through the heat sink 41 decreases and the heat exchange performance deteriorates. In this respect, the cooling module 22 can smoothly discharge the dust D, which is ejected toward the heat sink 41 together with air, to the outside of the chassis 14 through the opening portion 52 and the auxiliary opening portion 54, and can maintain the heat exchange performance for a long period of time.

The auxiliary opening portion 54 is located between at least the end 41b of the heat sink 41 that is located on the downstream side in the width direction, and the opening portion 52. That is, the auxiliary opening portion 54 is located at a position where the air A4 having the lowest air velocity flows in the width direction of the heat sink 41. Therefore, although the auxiliary opening portion 54 is provided, the heat sink 41 can suppress the amount of air flowing through the auxiliary opening portion 54 to the minimum necessary amount. Accordingly, the heat sink 41 can secure smooth discharge of the dust D while preventing the excessive air blow from the auxiliary opening portion 54 and the overall heat exchange performance from deteriorating. In particular, the auxiliary opening portion 54 is located at a position close to at least the end 41b of the heat sink 41 that is located on the downstream side in the width direction. Therefore, the dust D ejected to a rear surface of the heat sink 41 is pressed against a rear end surface of each fin 48, and a part of the dust D gradually moves from the upstream side to the downstream side. As a result, the dust D is guided to the auxiliary opening portion 54 located on the downstream side of the heat sink 41, and is more efficiently discharged to the outside.

In particular, the heat sink 41 is provided with the opening portion 52 in a central range in the width direction. Therefore, the dust D is relatively less likely to escape from both ends 41a and 41b at which the opening portion 52 is not provided. In this regard, since the heat sink 41 according to one or more embodiments is provided with the auxiliary opening portion 54 at least on the end 41b side, the dust D collected on the end 41b side can be smoothly discharged.

The heat sink 41 is configured such that the opening area of the auxiliary opening portion 54 is smaller than that of the opening portion 52. Therefore, the heat sink 41 can also prevent a situation in which a part of the air passing through the auxiliary opening portion 54 blows to the side (the end 41b side) in the width direction and returns to the intake port 43f. In particular, in the auxiliary opening portion 54, the opening portion located on the most end 41b side is closed to the vicinity of the outlet port 43a by a part of the portion 46b of the plate-like portion 46 located on the most end 41b side. Therefore, the auxiliary opening portion 54 can more reliably prevent the air blow to the side.

As described above, the cooling module 22 can prevent the clogging of the dust D in the heat sink 41 even in a case in which the electronic apparatus 10 is used for a long period of time or is used in a harsh environment in which there is a lot of debris, dirt, or the like (dust). As a result, the cooling module 22 can maintain the heat exchange performance in the heat sink 41 for a long period of time and can maintain the cooling performance for a longer period of time.

In addition, the auxiliary opening portion 54 can also be provided between the end 41a located on the upstream side and the opening portion 52. However, the auxiliary opening portion 54 may not be provided on the end 41a side. That is, in a case in which only the discharge efficiency of the dust D is taken into consideration, the auxiliary opening portion 54 may also be provided on the end 41a side. However, the air A1 having a high air velocity passes through the gap G between the fins 48A on the end 41a side. Therefore, in a case in which the auxiliary opening portion 54 is also provided on the end 41a side, there is a concern that the heat exchange performance of the entire heat sink 41 significantly deteriorates. Therefore, in order to achieve both the heat exchange performance and the discharge efficiency of the dust D, the heat sink 41 according to one or more embodiments is provided with the auxiliary opening portion 54 only on the end 41b side on the downstream side. In this case, the upper surface of the heat sink 41 on the end 41a side is closed to the vicinity of the outlet port 43a by the portion 46c of the plate-like portion 46. Therefore, the heat sink 41 can also prevent a part of the air A1 from blowing to the side (end 41a side) in the width direction of the heat sink 41, and the heat exchange performance is further improved.

The auxiliary opening portion 54 can be configured such that the opening area gradually decreases from the opening portion 52 toward the end 41b. Accordingly, the auxiliary opening portion 54 can secure smooth discharge of the dust D while more reliably preventing the air blow to the side (end 41b side) described above. That is, as illustrated in FIG. 5, since the auxiliary opening portion 54 is configured such that a side portion of the opening portion 52 is spread in a skirt shape, it is possible to secure more smooth discharge of the dust D from the opening portion 52.

The fin 48 can have the inclined shape portion 48c at a portion overlapping at least the opening portion 52 and the auxiliary opening portion 54 in the top-bottom direction. The inclined shape portion 48c is gradually inclined from an outlet side of the air to an inlet side (outlet port 43a side) in the longitudinal direction of the fins 48 in a direction from the plate-like portion 46 to the plate-like portion 47. Accordingly, the opening portion 52 and the auxiliary opening portion 54 can secure an enlarged space for allowing the dust D to pass through, between the opening portion 52 and the upper end surface of each fin 48, and the dust D is more smoothly discharged.

Here, an example of a method of manufacturing the heat sink 41 (40) according to one or more embodiments will be described. FIG. 7A is a front view of the auxiliary opening portion 54 of the heat sink 41 and a peripheral portion thereof in a disassembled manner. FIG. 7B is a front view illustrating a state in which the fins 48 illustrated in FIG. 7A are joined to each other.

As illustrated in FIGS. 4A, 4B, 7A, and 7B, the heat sink 41 (40) can be configured by laminating the plurality of fins 48 in which the plate pieces 48a and 48b are formed to be bent at upper and lower end portions in the upright direction and joining the plate pieces 48a and 48b to each other. The plate piece 48a is a fin-like portion in which one end portion (upper end portion) of the fin 48 in the upright direction is bent. The plate piece 48b is a fin-like portion in which the other end portion (lower end portion) of the fin 48 in the upright direction is bent. Each of the plate pieces 48a and 48b protrudes toward the adjacent fins 48. The plate pieces 48a and 48b protrude in the same direction.

In one or more embodiments, the fins 48 constitutes the plate-like portion 46 by the plate pieces 48a of the fins being arranged continuously adjacent to each other and formed into a plate shape. The fins 48 constitutes the plate-like portion 47 by the plate pieces 48b of the fins being arranged continuously adjacent to each other and formed into a plate shape.

As the fins 48 constituting the auxiliary opening portion 54, a predetermined number of fins 48, in which the lengths of the plate pieces 48a forming the plate-like portion 46 in the front-rear direction are changed from the other fins 48, are prepared. As the fins 48 constituting the opening portion 52, a predetermined number of fins 48, in which the lengths of the plate pieces 48a in the front-rear direction are shorter than the lengths of the fins 48 constituting the auxiliary opening portion 54, are prepared. Accordingly, the heat sink 41 can easily form the auxiliary opening portion 54 only by arranging and joining the fins 48. That is, the auxiliary opening portion 54 can be efficiently manufactured by laminating the fins 48 in which the lengths of the plate pieces 48a in the air flow direction are varied from each other. The fin 48A need only be configured such that the length in the front-rear direction is longer than those of the fins 48 constituting the opening portion 52.

FIG. 8 is a plan view of the heat sink 41 having a plate-like portion 46A according to a modification example. As illustrated in FIG. 8, the plate-like portion forming the upper surface of the heat sink 41 can also be configured as the plate-like portion 46A formed of one metal plate. In the plate-like portion 46A formed of one metal plate, the opening portion 52 and the auxiliary opening portion 54 can be formed by performing predetermined cutout processing on the edge portion 46a. In this case, the auxiliary opening portion 54 need only be formed by an inclined end surface 46d that is gradually inclined toward the outlet port 43a side (front side) from the opening portion 52 toward the end 41b. The plate-like portion 47 forming the lower surface can also be formed of one metal plate similar to the plate-like portion 46A.

In addition, the present invention is not limited to the above-described embodiments, and there is no doubt that the present invention can be freely changed without departing from the gist of the present invention.

### DESCRIPTION OF SYMBOLS

10 electronic apparatus
14 chassis
22 cooling module
30 CPU
31 GPU
38 heat pipe
40, 41 heat sink
41a, 41b end
42, 43 fan
43a outlet port
43g air path
46, 46A, 47 plate-like portion
48, 48A fin
48c inclined shape portion
52 opening portion
54 auxiliary opening portion

What is claimed is:

1. A cooling module that is mounted in an electronic apparatus, the cooling module comprising:
a fan having an outlet port; and
a heat sink having a plurality of fins arranged with a gap between the plurality of fins between a first plate-like portion and a second plate-like portion that extend along a width direction of the outlet port, the heat sink being disposed to face the outlet port,
wherein the first plate-like portion includes
an opening portion through which a part of air ejected from the outlet port is capable of being discharged, and
an auxiliary opening portion that is provided between at least one end located on a downstream side in an air flow direction in the fan in a longitudinal direction of the first plate-like portion and the opening portion, and through which a part of air ejected from the outlet port is capable of being discharged, and
an opening area of the auxiliary opening portion is smaller than an opening area of the opening portion.

2. The cooling module according to claim 1,
wherein the opening area of the auxiliary opening portion gradually decreases from the opening portion toward the one end.

3. The cooling module according to claim 2,
wherein the fin includes
a first plate piece of which a first end portion in an upright direction of the fin is bent and that protrudes toward an adjacent fin, and
a second plate piece of which a second end portion in an upright direction of the fin is bent and that protrudes toward an adjacent fin,
the plurality of fins constitutes the first plate-like portion by the first plate pieces of the plurality of fins being arranged continuously adjacent to each other and formed into a plate shape, and constitutes the second plate-like portion by the second plate pieces of the plurality of fins being arranged continuously adjacent to each other and formed into a plate shape, and
the auxiliary opening portion is configured such that lengths of the first plate pieces in the air flow direction in the heat sink are varied between adjacent fins.

4. The cooling module according to claim 1,
wherein the fin is provided with an inclined shape portion that is gradually inclined toward the outlet port in a direction from the first plate-like portion toward the second plate-like portion, at a portion overlapping at least the opening portion and the auxiliary opening portion in a top-bottom direction.

5. The cooling module according to claim 1,
wherein one or more of the plurality of fins are located at a position close to an end of the heat sink located on an upstream side in the air flow direction in the fan and have longer lengths in the air flow direction than one or more of the plurality fins located at other portions of the heat sink.

6. An electronic apparatus comprising:
a chassis;
a heating element provided in the chassis; and
a cooling module provided in the chassis and configured to cool the heating element,
wherein the cooling module includes
a fan having an outlet port, and
a heat sink having a plurality of fins arranged with a gap between the plurality of fins between a first plate-like portion and a second plate-like portion that extend along a width direction of the outlet port, the heat sink being disposed to face the outlet port,
the first plate-like portion includes
an opening portion through which a part of air ejected from the outlet port is capable of being discharged, and
an auxiliary opening portion that is provided between at least one end located on a downstream side in an air flow direction in the fan in a longitudinal direction of the first plate-like portion and the opening portion, and through which a part of air ejected from the outlet port is capable of being discharged, and
an opening area of the auxiliary opening portion is smaller than an opening area of the opening portion.

7. The electronic apparatus according to claim 6,
wherein the opening area of the auxiliary opening portion gradually decreases from the opening portion toward the at least one end.

8. The electronic apparatus according to claim 6, further comprising:
a heat pipe that thermally connects the heating element and the heat sink,
wherein the heat pipe is connected to the second plate-like portion.
